(19) United States
(12) Patent Application Publication
(10) Pub. No.: US 2016/0138152 A1
(43) Pub. Date: May 19, 2016

(54) EVAPORATION UNIT AND METHOD FOR EVAPORATING AN OBJECT WITH SAID TYPE OF EVAPORATION UNIT

(71) Applicant: Kennametal Inc., Latrobe, PA (US)

(72) Inventors: Alexander DRAKEN, Hohenau (DE); Rudolf Karl GRAU, Neustadt an der Aisch (DE); Rodrigue NGOUMENI YAPPI, Füssen (DE); Hubert Josef SCHWEIGER, Füssen (DE)

(21) Appl. No.: 14/897,535

(22) PCT Filed: Jun. 13, 2014
(86) PCT No.: PCT/EP2014/062431

§ 371 Date: Dec. 10, 2015

(30) Foreign Application Priority Data
Jun. 13, 2013 (DE) 10 2013 211 034.0

(51) Int. Cl. C23C 14/24; H05B 3/14; C23C 14/26

(52) U.S. Cl. CPC C23C 14/243; C23C 14/26; H05B 3/141

(57) ABSTRACT

In order to ensure that metal is homogeneously vaporized, in particular in a vacuum-strip vaporizer plant, a vaporization unit (2) is provided which has an inner cavity (6) which is defined by a circumferential web (10) to which an outer cavity (8) is connected.

### BACKGROUND OF THE INVENTION

The invention concerns a vaporizing unit according to the preamble of claim 1, as well as a method for vacuum-coating an object with the aid of such a vaporizing unit.

A vaporizing unit of this type can be found in U.S. 2011/013891 A1 or WO 2008/092423 A1, for example.

Such a vaporizing unit is designed as a ceramic body having a defined specific conductivity. For coating a flexible substrate with a metal, in particular aluminum, a vaporizing unit of this type is typically used in what is referred to as a vacuum strip metallization plant with the aid of the PVD (physical vapor deposition) technique. Flexible substrates can be paper, plastic films and also textiles, for example.

The vaporizing unit is heated via a resistance heater to a prescribed temperature, for example ranging between 1500° C. and 1900° C. The metal to be vaporized is fed in the form of a metal wire to a top side of the vaporizing unit, which metal wire initially melts before the molten metal is then vaporized under a vacuum of approximately 1⁻⁴ kPa (10⁻⁴ mbar). Vaporizing units often have a trough-like cavity on their top side for accommodating the molten metal.

For resistance heating, electrodes (in particular copper electrodes) respectively abut the opposite faces of the vaporizing unit, the electrodes normally being cooled to 250° C.

In principle, the goal is to wet the vaporizing unit as homogeneously and extensively as possible, while at the same time achieving high vaporization rates to facilitate a homogeneous metallization of the object being coated at a high rate of application. However, this goal can generally be achieved only with great difficulty. Among other things, this is due to the fact that metal wire is often not fed with precise centering into the vaporizing unit, thus resulting in the molten metal asymmetrically wetting the vaporizing surface. To some extent, this additionally causes the liquid metal to already reach the edge of the vaporizing unit on the one side and come in contact with the comparatively cool electrodes. This results in metal spatter, which is undesired for a high-quality coating. To prevent this, the temperature (and thereby the vaporization rate) can in principle be increased. However, as temperature increases so does the problem of what is referred to as chemical corrosion, thereby decreasing the overall service life of the vaporizing unit. Evaporator units typically have a service life ranging between 5 and 25 operating hours, for example.

A sought-after homogeneous, complete wetting of a defined vaporizer surface area (formed by a cavity, for example) is as a rule rarely achieved. When a vaporizing unit of this type is operated, generally only a partial region of the vaporizer surface area formed by the cavity is wetted.

Another problem related to the incomplete wetting of the vaporizer surface can be seen in the fact that, due to the absence of cooling via the liquefied metal in the unwetted partial regions, these partial regions have a markedly higher temperature. These regions are also referred to as “hot spots”. These in part reach temperatures in excess of 2000° C., which can result in damage to and destruction of the vaporizing unit.

### OBJECT OF THE INVENTION

Proceeding from this point, the invention is based on the object of enabling a complete wetting of a vaporizer surface, particularly without entailing the risk of the molten metal on the edge of the vaporizing unit coming into contact with the electrodes, and thereby also preventing spatter.

### ACHIEVEMENT OF THE OBJECT

The object is achieved according to the invention by a vaporizing unit having the features of claim 1, as well as by a method with the features of claim 11. The presented advantages and preferred embodiments with regard to the vaporizing unit are also to be reasonably applied to the method.

The vaporizing unit features a top side which comprises a vaporizer surface for vaporizing metal. An inner cavity is introduced into the top side, the inner cavity being defined by a surrounding web against which an outer cavity in turn abuts. In this way the inner cavity forms an inner vaporizer surface and the outer cavity an outer vaporizer surface. This means that the outer cavity is also sufficiently heated by the heater during operation so that molten material which arrives in the outer cavity is vaporized.

The surrounding web is therefore a type of collection pan that is laterally defined by the surrounding web. The collection pan receives the molten material to be vaporized. This material is usually fed from above in the form of a wire. The wire melts due to the hot vaporizing unit.

The inner cavity thereby forms an inner primary vaporizing surface, while the outer cavity functions in particular as overflow protection. This inner cavity is generally designed as an (in particular central) basin-shaped depression which is designed to accommodate the molten material to be vaporized during operation, and thus accordingly features a floor and lateral defining walls.

Proceeding from the knowledge that in conventional s only a limited area of the top side is wetted, the vaporizing unit described here is therefore deliberately furnished from the beginning with only a limited area of the top side as this primary vaporization surface, via the design of the inner cavity. This is completely wetted during operation, wherein the surrounding web functions to ensure that a uniform, complete wetting of the inner vaporization surface occurs even if the metal wire is fed off-center. The flow of the metal is limited by the surrounding web and—even if fed off-center from the edge—the metal thus disperses into the remaining free dispersion direction. Because of the complete wetting and the homogeneous distribution of the molten metal within the inner cavity, a homogeneous, uniform temperature distribution also appears, whereby a homogeneous vaporization is achieved. This homogeneous temperature distribution also allows a suitable, not excessively high operating temperature to be set, thereby decreasing the strain on the vaporizing unit as compared to conventional vaporizing units. In particular, the problem of chemical corrosion is decreased.

Another special advantage of this inner cavity can also be found in the fact that, via the complete filling of the inner cavity with molten metal, the flow rate of the molten metal is decreased overall in comparison to that of conventional vaporizing units in which the molten metal is not limited by a surrounding web. In this way, the strain on the vaporizing unit that results from what are referred to as washouts, which typically appear in the center, are markedly reduced.

Another important aspect can be seen in the outer cavity. Namely, in the event that the molten metal overflows the web—for example as a result of a high feed rate—this overflowing portion of the molten material is reliably captured in the outer cavity. This thus provides an additional outer or secondary vaporizing surface. This reliably prevents the risk of liquid metal coming into contact with the cooled electrodes, which would thereby result in metal spatter.

The outer cavity is therefore purposefully designed as a surrounding channel, such that the outer cavity completely surrounds the inner cavity. The two cavities are thus continuously separated from one another by means of the web.

The outer cavity is expediently integrated continuously into the top side along the edge. At least nearly the entire surface of the top side is thus enclosed by the outer cavity. There are no further cavities outside of the outer cavity. In addition, the inner cavity preferably covers completely the area of the top side surrounded by the outer cavity—except for the clearance of the outer cavity as defined by the web. Thus only a single central inner, trough-shaped cavity is present. This cavity features a continuous, uninterrupted floor, which in particular also has no separating webs or depressions.

The setting of a desired vaporization temperature is very sensitive owing to various influencing factors such as, for example, the heat output of the resistance heater on the one hand and the feed rate and cooling performance of the molten material on the other hand, and also depends in particular on the ratio of the wetted area to the total surface. In this case, the inner vaporizing surface preferably constitutes between 25% and 85%, and in particular between 40% and 65%, of the total surface area of the top side of the vaporizing unit.

Vaporizing units of this type typically feature a top side having a width of 25 to 50 mm, for example, in particular 35 mm, and a length in a range of 100 to 150 mm, in particular 130 mm. The typical material thickness of such vaporizing units is 8 to 15 mm, in particular 10 mm.

The width of the inner cavity is generally equivalent to, for example, 30% to 60% of the total width of the vaporizing unit. At the same time, the length of the inner cavity is preferably in the range of 60% to 80% of the total length of the cavity. The desired homogeneous wetting of the inner vaporizing surface can be reliably achieved within these proportions.

In principle, the web functions primarily to define the inner cavity and demarcate the outer cavity. The web width preferably measures between 0.5 mm and 5 mm, particularly between 1 mm and 4 mm.

For the same purpose, namely to reliably ensure a complete and homogeneous wetting of the entire inner vaporizing surface, the inner cavity has a depth determined in particular by the web, which depth measures between 0.1 mm and 5 mm, particularly between 0.3 mm and 3 mm.

According to an expedient refinement, the outer cavity is deeper than the inner cavity. This provides the special advantage that the outer vaporizing surface has a higher temperature due to the somewhat lower material thickness, thereby ensuring a certain vaporization of any overflowing molten material. Alternatively, the cavities have the same depth or the outer cavity is shallower than the inner cavity. The embodiment also depends on a desired temperature to be set in the outer cavity, which is also influenced by the cross-sectional shape of the vaporizing unit.

As already explained, the outer cavity functions as a secondary vaporizing surface and correspondingly has a markedly smaller vaporizing surface in comparison to the inner cavity. In particular, the outer cavity has an outer vaporizing surface in a range of 10% to 35% of the inner vaporizing surface.

In addition, the inner cavity is preferably shaped corresponding to the peripheral contour of the vaporizing unit. Because this is usually of rectangular form, the inner cavity is likewise preferably of rectangular form. In principle, the vaporizing unit is of elongated form, so that in general the inner cavity is likewise elongated. An ovular form is also possible instead of a rectangular form. The web preferably has a respectively identical wall thickness all the way around, so that the outer cavity has the same outer contour as the inner cavity.

When operated for vapor-coating a flexible object in particular—for example a foil—the vaporizing unit is integrated into an electrical circuit by means of the aforementioned electrodes and heated via electric resistance. The vaporizing unit is thereby typically heated to a temperature of 1500° C. to 1700° C., for example. The metal to be vaporized, typically aluminum, is usually fed continuously as a wire into the inner cavity, where it then melts. The heat output for heating the vaporizing unit (determined by the electrical current) on the one hand and a feed rate of the metal being vaporized on the other hand are thereby matched to one another such that the inner cavity is covered completely with the melted metal. This thus constitutes a virtually stationary condition. Via the surrounding web, and the collection pan that is thereby formed, said collection pan is thus filled with molten metal such that the entire inner vaporizing surface is covered with the molten metal.

### DESCRIPTION OF FIGURES

An exemplary embodiment of the invention is explained in greater detail on the basis of Figures. These show, via simplified illustrations:

FIG. 1 a top view of the top side of a vaporizing unit,

FIG. 2 a sectional view through the vaporizing unit as shown in FIG. 1 along section line A-A,

FIG. 3 a top view of the vaporizing unit as shown in FIG. 1, in operation, and

FIG. 4 a schematic illustration of a vacuum strip vaporization plant.

Parts that function in the same manner have the same reference numbers in Figures.

### DESCRIPTION OF THE EXEMPLARY EMBODIMENT

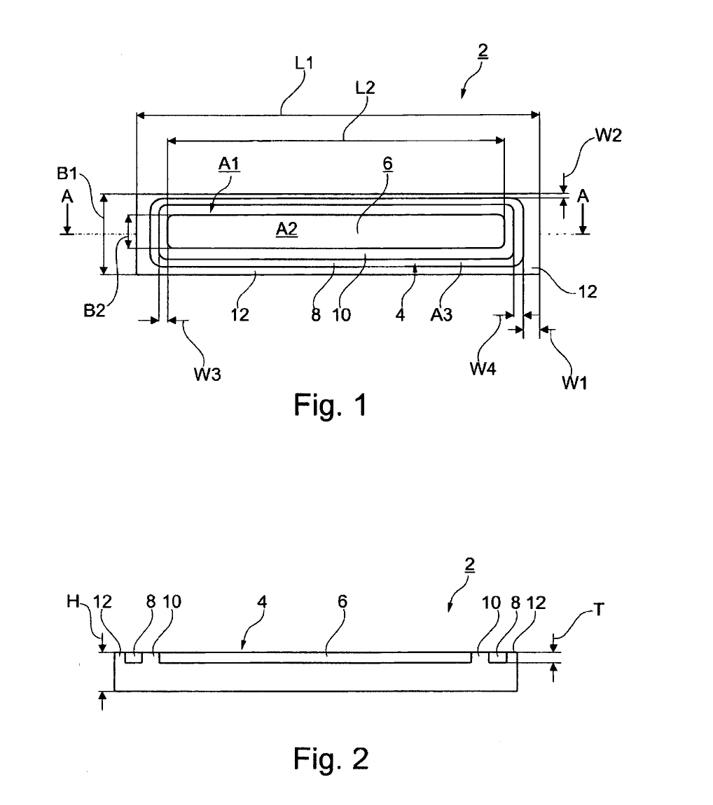

The ceramic vaporizing unit 2 illustrated in FIGS. 1 and 2 has an approximately rectangular top side 4 with a total surface area Al into which an inner cavity 6 and an outer cavity 8 are incorporated. The inner cavity 6 is likewise approximately rectangular. It is surrounded by a circumferential web 10 which separates the two cavities 6.8 from one another. The outer cavity 8 is in turn surrounded by a continuous edge 12 of the top side 4.

The inner cavity 6 defines an inner vaporizing surface area A2 defined by a web 10 and constituting a primary vaporizing surface. It is approximately basin-like in design and delimited below by a floor and laterally by the side wall defined by the web 10.

The outer cavity 8 is designed as a channel running around the inner cavity 6 and around the web 10, and inasmuch constitutes an outer vaporizing surface A3 or also an auxiliary or secondary vaporizing surface.

The inner cavity 6 has a length L2 as well as a width B2 which are less than total length L1 and a total width B1, respectively, of a top side 4. The total length L1 is typically in the range of 130 mm, for example, while the total width B is typically in the range of 35 mm. The height H of the vaporizing unit 2 is in the range of 10 mm, for example.

The vaporizing unit 2 is a ceramic body with defined electrical conductivity or, respectively, defined electrical specific resistance.

The vaporizing unit 2 comprises an outer edge 12 running around the outer cavity 8 and having at its faces a wall thickness W1 ranging between 4 and 10 mm, for example, and having at its longitudinal sides a lower wall thickness W2 ranging between 2 and 3 mm, for example.

The web 10 has in particular a constant web width W3 preferably between 1 mm and 4 mm, for example. The outer cavity 8 in turn has a channel width W4.

Finally, the web 10 has a web height which at the same time also defines a depth T of the cavities 6.8. In contrast to the exemplary embodiment shown, the two cavities 6.8 can also be of differing depth. In this case, it is preferable that the outer cavity 8 is deeper than the inner cavity 6.

As can additionally be learned from FIG. 2, the web 10—when viewed in cross section—has an approximately rectangular profile so that its side walls (which respectively define the respective cavities 6.8) are oriented approximately vertically. As already mentioned, the outer cavity 8 is designed in the form of a channel with a rectangular or also U-shaped or semicircular cross section.

The geometric data of the cavities 6,8, as well as of the web 10 and the edge 12, are collectively selected such that the inner vaporizing surface A2, defined by inner cavity 6 enclosed by the continuous web 10, constitutes approximately 40% to 65% of the area of the total surface area A1 of the top side 4. The channel width W4 as well as the web width W3 are approximately the same size and range between 2 and 5 mm, for example. They are separated from the peripheral edge at the same respective distance at both the faces and the longitudinal sides of the vaporizing unit 2, such that the inner cavity 6 is arranged centrally. In this case, the edge 12 is narrower on the longitudinal side than on the face.

In the exemplary embodiment, the width B2 of the inner cavity 6 is between 16 mm and 18 mm, for example, thus generally somewhere between 45% and 50% of the total width B1 of typically 35 mm. The length L2 of the inner cavity 6 between 90 and 100 mm, for example, and therefore generally approximately between 70% and 80% of the total length L of typically 130 mm.

When viewed in cross section running perpendicular to the longitudinal direction of the vaporizing unit 2, the unit has either a rectangular or a trapezoidal cross sectional area, wherein the long side of the trapezoid defines the top side 4.

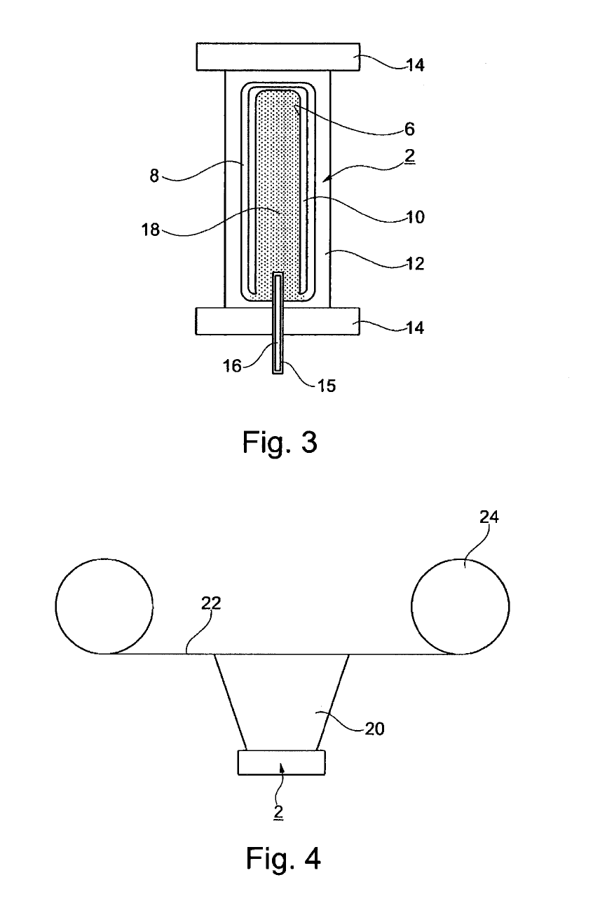

The function and mode of operation of the vaporizing unit 2 during the actual vaporizing process are explained in detail below, aided by FIG. 3.

During operation, the vaporizing unit 2 is clamped between two electrodes 14 (typically made of copper) and an electric current flows through the unit. As a result, the vaporizing unit 2 is heated to approximately 1700° C., for example. At the same time, a metal to be melted (particularly in the form of a metal wire 16) is continuously and successively introduced into the inner cavity 6 with the aid of a feed device 15, such that the metal melts and forms a molten material 18. The current through the vaporizing unit 2 (and thus the temperature thereof) as well as the feed rate of the metal wire are regulated in harmony with one another such that the inner vaporizing unit A2 is completely wetted with a molten metal in a virtually stationary state. This is facilitated and enabled due to the definition of the inner cavity 6 by the continuous web 10. The inner cavity 6 is thus at least partly filled by the molten material.

The metal used is typically aluminum. The molten aluminum typically has a temperature of approximately 650° C., and therefore cools the surface of the inner cavity 6. Because of the homogeneous wetting, this cooling effect is uniformly distributed over the entire surface area of the cavity 6, and therefore none of what are referred to as “hot spots” appear.

Owing to the molten metal 18 being enclosed by the web 10, the flow rate of the molten material 18 is also comparatively low. This results in lower strain on the vaporizing unit 2. Because of the high temperatures, namely the liquid aluminum reacts very aggressively with the material of the vaporizing unit 2, which leads to what are referred to as washouts as a result of what is referred to as chemical corrosion. The washouts are thus reduced compared to a conventional vaporizing unit 2.

The service life of the vaporizing unit 2 is thereby increased because this chemical corrosion acts selectively on the components of the vaporizing unit 2. In particular, this chemical corrosion leads to a washout of the non-conductive material portions of the vaporizing unit 2, such that overall the electrical conductivity is successively increased during operation. To maintain sufficient heat output, the current is thus successively increased. The current is typically provided by a transformer. As soon as the current limit of the transformer is reached, the vaporizing unit 2 must be exchanged. This typically occurs following several operating hours.

As is also to be learned in particular from FIG. 3, an off-center feed of the metal wire 16 is also enabled without problems, wherein the homogeneous wetting of the inner cavity 6 is ensured at the same time.

Under certain circumstances, off-centered feeding can in particular result in the molten material 18 flowing over the web 10 into the feed area, for example. The overflowing portion of the molten material 18 is trapped by the outer cavity 8, where it is then vaporized. This reliably ensures that the molten material 18 does not come into contact with the cooled electrodes 14, thereby reliably preventing possible metal spatter.

FIG. 4 shows a highly simplified illustration of a vacuum strip vaporizer plant with the aid of a vaporizing unit 2 of this type. The entire vaporizing process is in this case performed under a vacuum of 1⁻⁴ kPa (10⁻⁴ mbar). The vaporizing unit 2 produces the vaporization of the metal from the molten material 18. The metal vapor 20 created in this process precipitates on a continuously fed band 22 (e.g., a plastic film) to be coated. This is taken up by a cooling roller 24.

1. Vaporizing unit with a top side wherein
an inner cavity is incorporated in the top side, the inner cavity being defined by a surrounding web to which in turn an outer cavity is connected.

2. The vaporizing unit according to claim 1, wherein
the outer cavity is designed as a surrounding channel.

3. The vaporizing unit according to claim 1, wherein
that the outer cavity and the web are designed along the peripheral edge of the top side, and the inner cavity completely covers the area enclosed by the web.

4. The vaporizing unit according to claim 1, wherein
the inner cavity has an inner vaporizing surface which is between 25% and 85% and in particular between 10% and 65% of the total surface area of the top side.

5. The vaporizing unit according to claim 1, wherein
the inner cavity has a width ranging between 30% and 60% of a total width of the top side and a length ranging between 60% and 80% of a total length of the top side.

6. The vaporizing unit according to claim 1, wherein
the web has a web width of between 0.5 mm and 5 mm, and in particular between 1 mm and 4 mm.

7. The vaporizing unit according to claim 1, wherein
the inner cavity and the outer cavity both have a depth of between 0.1 mm and 5 mm, and in particular between 0.3 mm and 3 mm.

8. The vaporizing unit according to claim 1, wherein
the outer cavity is deeper than the inner cavity.

9. The vaporizing unit according to claim 1, wherein
the outer cavity has an outer vaporizing surface area ranging between 15% and 35% of an inner vaporizing surface area of the inner cavity.

10. The vaporizing unit according to claim 1, wherein
the inner cavity is of rectangular form.

11. Method for vacuum-coating an object with the aid of the vaporizing unit according to claim 1, wherein the vaporizing unit is heated and a metal to be vaporized is fed into the inner cavity, where it melts and vaporizes, wherein a heat output for heating the vaporizing unit and a metal feed rate are coordinated such that the inner cavity is completely covered with molten metal.

12. The vaporizing unit according to claim 1, wherein the inner cavity has an inner vaporizing surface which is between 40% and 65% of the total surface area of the top side.

13. The vaporizing unit according to claim 1, wherein the inner cavity and the outer cavity both have a depth of between 0.3 mm and 3 mm.
